(19) United States
(12) Patent Application Publication
(10) Pub. No.: US 2025/0234510 A1
(43) Pub. Date: Jul. 17, 2025

(54) SEMICONDUCTOR DEVICE AND METHOD OF MANUFACTURING THE SAME

(71) Applicant: Samsung Electronics Co., Ltd., Suwon-si, Gyeonggi-do (KR)

(72) Inventor: Jungbum LIM, Suwon-si (KR)

(73) Assignee: Samsung Electronics Co., Ltd., Suwon-si, Gyeonggi-do (KR)

(21) Appl. No.: 18/991,921

(22) Filed: Dec. 23, 2024

(30) Foreign Application Priority Data
Jan. 15, 2024 (KR) 10-2024-0006302

(51) Int. Cl. H10B 12/00

(52) U.S. Cl. CPC H10B 12/315; H10B 12/033

(57) ABSTRACT

A semiconductor device comprising a substrate including a chip area and an edge area surrounding the chip area, a plurality of capacitor structures in the chip area of the substrate, a plurality of dummy structures in the edge area of the substrate, and an interlayer insulating layer covering the plurality of capacitor structures and the plurality of dummy structures. Each of the plurality of dummy structures comprises a plurality of slits, and the plurality of slits are filled with the interlayer insulating layer.

### CROSS-REFERENCE TO RELATED APPLICATION

This application is based on and claims priority under 35 U.S.C. § 119 to Korean Patent Application No. 10-2024-0006302, filed on Jan. 15, 2024, in the Korean Intellectual Property Office, the disclosure of which is incorporated by reference herein in its entirety.

### BACKGROUND

The inventive concepts relates to a semiconductor device and a method of manufacturing the same. More particularly, the inventive concepts relates to a semiconductor device including a capacitor and a method of manufacturing the semiconductor device.

According to the trend of high integration in semiconductor devices, individual circuit patterns forming the semiconductor devices are increasingly miniaturized. That is, as the integration of semiconductor devices increases, the design rules regarding components of the semiconductor devices decrease. Accordingly, there is a demand for semiconductor devices capable of maintaining electrical characteristics by overcoming limitations on the design rules.

### SUMMARY

The inventive concepts provides a semiconductor device with improved reliability.

According to various example embodiments of the inventive concepts, there is provided a semiconductor device comprising a substrate including a chip area and an edge area surrounding the chip area, a plurality of capacitor structures in the chip area of the substrate, a plurality of dummy structures in the edge area of the substrate, and an interlayer insulating layer covering the plurality of capacitor structures and the plurality of dummy structures. Each of the plurality of dummy structures comprises a plurality of slits, and the plurality of slits are filled with the interlayer insulating layer.

According to other various example embodiments of the inventive concepts, there is provided a semiconductor device comprising a substrate including a chip area and an edge area surrounding the chip area, a lower structure arranged on the substrate and comprising a plurality of conductive areas, a plurality of capacitor structures arranged on the lower structure in the chip area, a plurality of dummy structures arranged on the lower structure in the edge area, and an interlayer insulating layer covering the plurality of capacitor structures and the plurality of dummy structures. Each of the plurality of dummy structures includes a plurality of slits, and the plurality of slits are filled with the interlayer insulating layer.

According to other various example embodiments of the inventive concepts, there is provided a semiconductor device comprising a substrate including a chip area and an edge area surrounding the chip area, the chip area includes a memory cell area and a core area surrounding the memory cell area, the edge area comprises a dummy cell area and a dummy core area surrounding the dummy cell area, a lower structure is arranged on the substrate and includes a plurality of conductive areas, a plurality of capacitor structures arranged on the lower structure in the memory cell area, a plurality of dummy structures arranged on the lower structure in the dummy cell area, and an interlayer insulating layer covering the plurality of capacitor structures and the plurality of dummy structures. Each of the plurality of dummy structures comprises a plurality of slits that are arranged apart from each other in an extension direction of the plurality of dummy structures, and the plurality of slits are filled with the interlayer insulating layer.

### BRIEF DESCRIPTION OF THE DRAWINGS

Various example embodiments of the inventive concepts will be more clearly understood from the following detailed description taken in conjunction with the accompanying drawings in which:

FIG. 1 is a plan view of a semiconductor device according to various example embodiments;

FIG. 2 illustrates a schematic layout of a chip area of a semiconductor device, according to various example embodiments;

FIG. 3 illustrates a schematic layout of an edge area of a semiconductor device, according to various example embodiments;

FIG. 4 is a cross-sectional view of a semiconductor device taken along a line A-A′ of FIG. 2;

FIG. 5 is a cross-sectional view of a semiconductor device taken along a line B-B′ of FIG. 3;

FIG. 6 illustrates a schematic layout of an edge area of a semiconductor device, according to various example embodiments;

FIG. 7 illustrates a schematic layout of an edge area of a semiconductor device, according to various example embodiments; and

FIGS. 8A, 8B, 9, 10, 11A, 11B, 12A, 12B, 13A, and 13B respectively are cross-sectional views of a method of manufacturing a semiconductor device, according to various example embodiments.

### DETAILED DESCRIPTION

Hereinafter, various example embodiments of the inventive concepts are described in detail with reference to the attached drawings. Like reference numerals in the drawings denote like elements, and repeated descriptions thereof will be omitted.

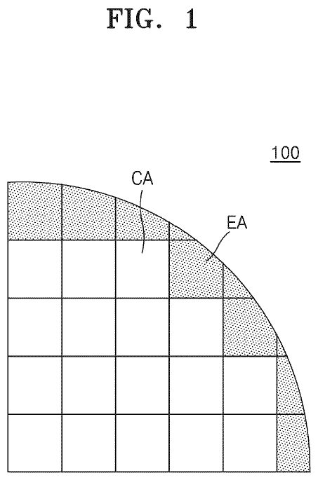

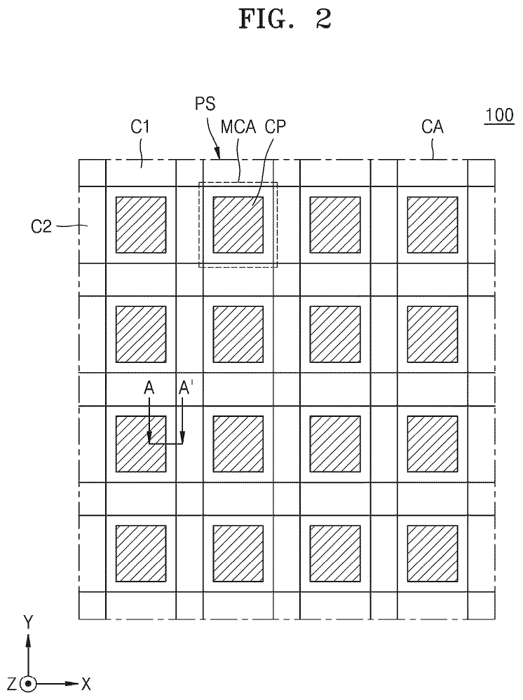

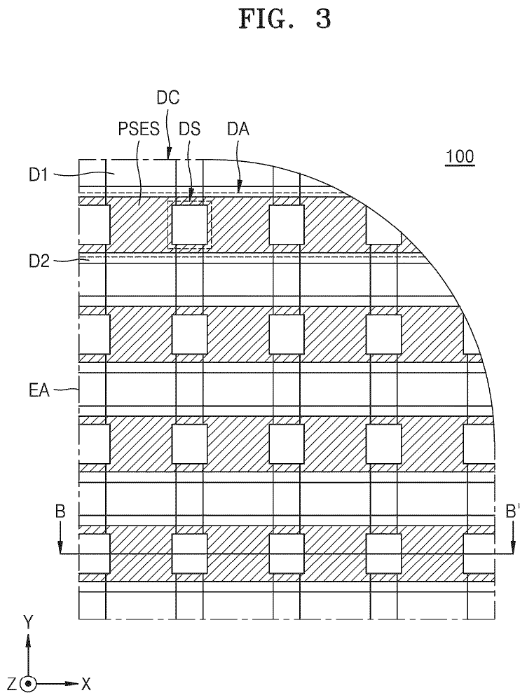

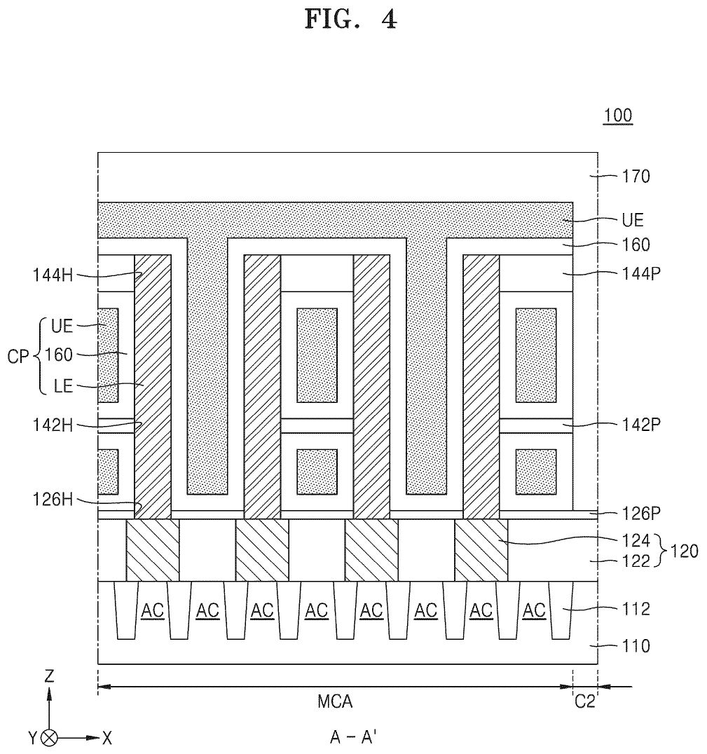

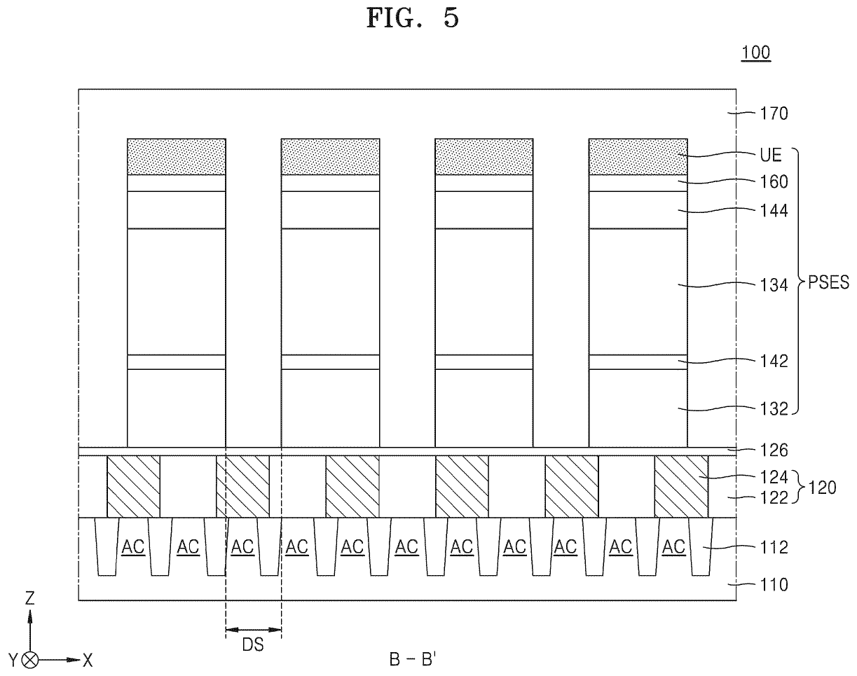

FIG. 1 is a plan view of a semiconductor device 100 according to various example embodiments. FIG. 2 illustrates a schematic layout of a chip area CA of the semiconductor device 100, according to various example embodiments. FIG. 3 illustrates a schematic layout of an edge area EA of the semiconductor device 100, according to various example embodiments. FIG. 4 is a cross-sectional view of a semiconductor device taken along a line A-A′ of FIG. 2. FIG. 5 is a cross-sectional view of a semiconductor device taken along a line B-B′ of FIG. 3.

Referring to FIGS. 1, 2, 3, 4, and 5, the semiconductor device 100 may include a plurality of chip areas CA and a plurality of edge areas EA. The chip areas CA may be arranged in a central region of the semiconductor device 100, while the edge areas EA are arranged to surround the chip areas CA in edge portions of the semiconductor device 100.

One chip area CA may include a plurality of memory cell areas MCA and a core area PS. Each memory cell area MCA may be surrounded by the core area PS. Each of the memory cell areas MCA may be an area where a memory cell array of a dynamic random access memory (DRAM) device is arranged. In each memory cell area MCA, a capacitor structure CP of the DRAM device may be arranged.

The core area PS may be an area where peripheral circuit devices required for the operation of the DRAM device are arranged. The core area PS may include a first core area C1 and a second core area C2. The first core area C1 may be a bit-line sense amplifier (S/A) block of the DRAM device, and the second core area C2 may be a sub-word line driver (SWD) block of the DRAM device. The bit-line sense amplifier arranged in the first core area C1 may sense and amplify data of a memory cell and store the data in the memory cell. The SWD arranged in the second core area C2 may select word lines of a memory cell and drive the selected word lines.

In the core area PS, the first core area C1 may extend in a second horizontal direction (a Y direction), and the second core area C2 may extend in a first horizontal direction (an X direction). The second horizontal direction (the Y direction) may correspond to an extension direction of a bit line arranged in the memory cell area MCA, and the first horizontal direction (the X direction) may correspond to an extension direction of a word line arranged in the memory cell area MCA.

One edge area EA may include a plurality of dummy cell areas DA and a dummy core area DC. Each dummy cell area DA may be surrounded by the dummy core area DC. In the edge area EA, dummy structures PSES may be arranged.

The dummy cell areas DA may correspond to the memory cell areas MCA of the chip area CA and extend relatively longer than the memory cell areas MCA in the first horizontal direction (the X direction).

The dummy core area DC may correspond to the core area PS of the chip area CA. The dummy core area DC may include a first dummy core area D1 and a second dummy core area D2. In the dummy core area DC, the first dummy core area D1 may extend in the second horizontal direction (the Y direction), and the second dummy core area D2 may extend in the first horizontal direction (the X direction).

Referring to FIGS. 4 and 5, the semiconductor device 100 may include, in the chip area CA, a substrate 110 including a plurality of active areas AC, a lower structure 120 on the substrate 110, and a plurality of capacitor structures CP arranged on the lower structure 120 and may include, in the edge area EA, the substrate 110 including the active areas AC, the lower structure 120 on the substrate 110, and a plurality of dummy structures PSES on the lower structure 120.

The substrate 110 may include a semiconductor element, such as Si or Ge, or a compound semiconductor, such as SiC, GaAs, InAs, or InP. However, example embodiments are not limited thereto. The substrate 110 may include a semiconductor substrate, at least one insulating layer formed on the semiconductor substrate, or structures including at least one conductive area. The conductive area may include, for example, a well doped with impurities or a structure doped with impurities.

On the substrate 110, a device isolation layer 112 defining the active areas AC may be formed. The device isolation layer 112 may include an oxide layer, a nitride layer, or a combination thereof. In various example embodiments, the device isolation layer 112 may have various structures, such as a shallow trench isolation (STI) structure.

The lower structure 120 may include a plurality of conductive areas 124 and a plurality of insulating structures 122. The conductive areas 124 may penetrate the lower structure 120 in a vertical direction (a Z direction) and be connected to the active areas AC. The conductive areas 124 may be insulated from each other by the insulating structures 122. The insulating structures 122 may each include an insulating layer including a silicon oxide layer, a silicon nitride (SIN) layer, or a combination thereof. In some example embodiments, the insulating structures 122 may each include various conductive areas, for example, a wire layer, a contact plug, and a transistor, and an insulating layer that insulates the above conductive areas from each other.

The conductive areas 124 may include polysilicon, metal, conductive metal nitride, metal silicide, or a combination thereof. However, example embodiments are not limited thereto. The conductive areas 124 may include, for example, a plurality of bit lines.

An insulating pattern 126P may be arranged on the lower structure 120. In the chip area CA, the insulating pattern 126P may include a plurality of openings 126H overlapping the conductive areas 124 in the vertical direction (the Z direction). On the other hand, in the edge area EA, the insulating pattern 126P may not include openings. The insulating pattern 126P may include a SiN layer, a silicon carbonitride (SiCN) layer, a silicon boron nitride (SiBN) layer, or a combination thereof. However, example embodiments are not limited thereto. The terms “SiN,” “SiCN,” and “SiBN” used in the present specification denote materials containing elements included in the above terms, but they are not chemical formulas indicating a stoichiometric relation.

In the chip area CA, a plurality of capacitor structures CP may be arranged in the conductive areas 124. The capacitor structures CP may include a plurality of lower electrodes LE, a plurality of dielectric layers 160, and an upper electrode UE.

The lower electrodes LE may be arranged in the conductive areas 124, respectively. The lower electrodes LE may respectively have pillar shapes extending in a direction away from the substrate 110 along the vertical direction (the Z direction), penetrating the insulating pattern 126P through the openings 126H. Each lower electrode LE may have a bottom surface contacting an upper surface of a selected one of the conductive areas 124 to be connected to the selected conductive area 124.

FIG. 2 illustrates that each lower electrode LE has a pillar shape, but various example embodiments are not limited thereto. For example, each lower electrode LE may have a cross-sectional structure having a cup shape or a cylinder shape with a closed bottom.

The lower electrodes LE may be supported by a lower supporter 142P and an upper supporter 144P. The lower electrodes LE and the upper electrode UE may face each other with the dielectric layer 160 therebetween.

The upper supporter 144P may surround an upper end portion of each lower electrode LE and extend in parallel with the substrate 110. The upper supporter 144P may include a plurality holes 144H through which the lower electrodes LE penetrate. The inner sidewall of each hole 144H formed in the upper supporter 144P may be in contact with the sidewall of the lower electrode LE. The upper surface of each lower electrode LE may be on the same plane as the upper surface of the upper supporter 144P.

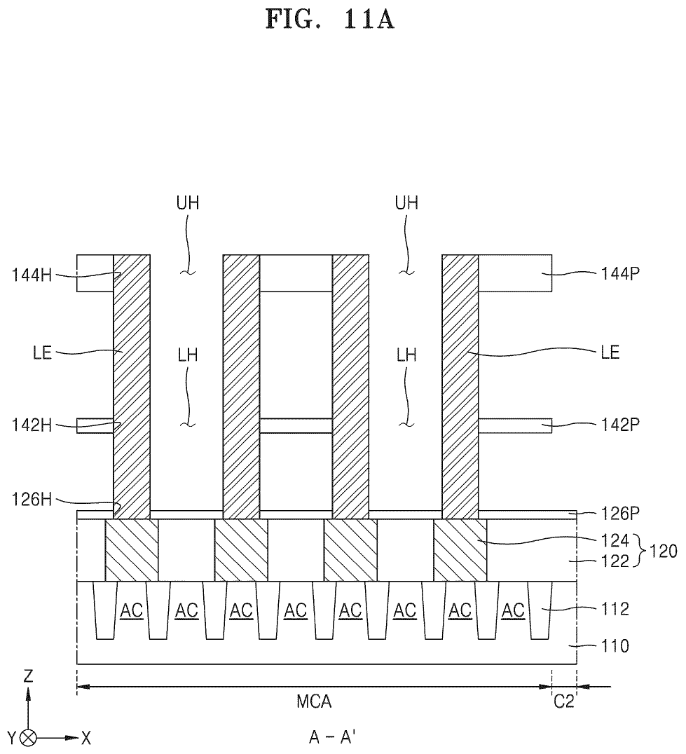

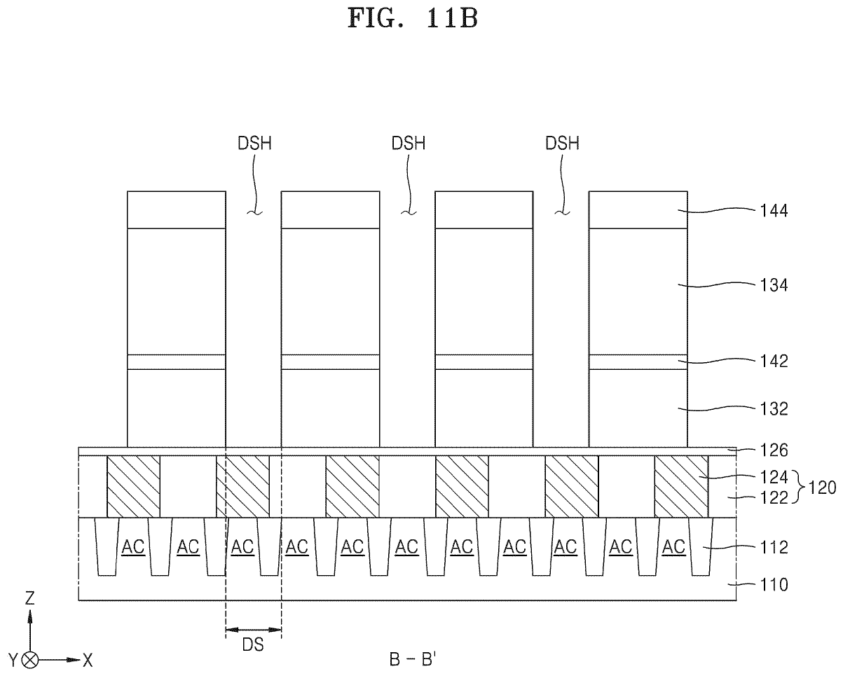

The lower supporter 142P may extend between the substrate 110 and the upper supporter 144P in parallel with the substrate 110. In the lower supporter 142P, a plurality of holes 142H, through which the lower electrodes LE penetrate, and a plurality of lower holes LH (see FIG. 11A) may be formed. The inner sidewall of each hole 142H formed in the lower supporter 142P may be in contact with the sidewall of the lower electrode LE.

The lower supporter 142P and the upper supporter 144P may each include a SiN layer, a SiCN layer, a SiBN layer, or a combination thereof, but example embodiments are not limited thereto. In some example embodiments, the lower supporter 142P may include the same material as the upper supporter 144P. For example, the lower supporter 142P and the upper supporter 144P may each include SiCN. In some example embodiments, the lower supporter 142P and the upper supporter 144P may include different materials. For example, the lower supporter 142P may include SiCN, while the upper supporter 144P may include SiBN.

The dielectric layer 160 may be between the lower electrode LE and the upper electrode UE. The dielectric layer 160 may include, for example, silicon nitride, silicon oxide, silicon oxynitride, or a combination thereof. However, example embodiments are not limited thereto. The dielectric layer 160 may include a high-k dielectric material with a higher permittivity than silicon. The high-k dielectric material may include, for example, hafnium oxide (HfO₂), hafnium silicon oxide (HfSiO₄), lanthanum oxide (LaO), zirconium oxide (ZrO₂), zirconium silicon oxide (ZrSiO), tantalum oxide (Ta₂O₅), titanium oxide (TiO₂), barium strontium titanium oxide (BaSrTiO₄), barium titanium oxide (BaTiO₃), strontium titanium oxide (SrTiO₃), lithium oxide (Li₂O), aluminum oxide (Al₂O₃), lead scandium tantalate (PST), lead zinc niobate (PZN), or a combination thereof. However, example embodiments are not limited thereto.

The upper electrode UE may cover the dielectric layer 160 and may be spaced apart from the lower electrodes LE with the dielectric layer 160 therebetween.

The lower electrodes LE and the upper electrode UE may each include metal, conductive metal oxide, conductive metal nitride, conductive metal oxynitride, or a combination thereof. However, example embodiments are not limited thereto. In some example embodiments, the lower electrodes LE and the upper electrode UE may each include Ti, TiO₂, titanium nitride (TiN), titanium oxynitride (TION), cobalt (Co), cobalt oxide (CoO), cobalt nitride (CON), cobalt oxynitride (CoNₓO_{y}), niobium (Nb), niobium oxide (NbO), niobium nitride (NbN), niobium oxynitride (NbON), tin (Sn), tin oxide (SnO₂), tin nitride (SnN), tin oxynitride (SnON), or a combination thereof. However, example embodiments are not limited thereto. For example, the lower electrodes LE and the upper electrode UE may each include TIN, CON, NbN, SnO₂, or a combination thereof, but the materials forming each of the lower electrodes LE and the upper electrode UE are not limited thereto.

In the edge area EA, the dummy structures PSES may be arranged in the conductive areas 124. Each dummy structure PSES may extend in the first horizontal direction (the X direction). In addition, the dummy structures PSES may be spaced apart from each other in the second horizontal direction (the Y direction). Each dummy structure PSES may include a first mold layer 132, a lower supporter layer 142, a second mold layer 134, an upper supporter layer 144, the dielectric layer 160, and the upper electrode UE.

The first mold layer 132, the lower supporter layer 142, the second mold layer 134, the upper supporter layer 144, the dielectric layer 160, and the upper electrode UE may be sequentially stacked on the insulating pattern 126P in the edge area EA. In various example embodiments, the first mold layer 132 and the second mold layer 134 may each include an oxide layer, a nitride layer, or a combination thereof. For example, the first mold layer 132 may include a borophosphosilicate glass (BPSG) layer, and the second mold layer 134 may include a multilayered insulating layer in which a relatively thin silicon oxide layer and a relatively thin silicon nitride layer are alternately stacked one by one several times, or a silicon nitride layer. However, the materials forming each of the first mold layer 132 and the second mold layer 134 are not limited thereto. The lower supporter layer 142 and the upper supporter layer 144 may each include a SiN layer, a SiCN layer, a SiBN layer, or a combination thereof. In some example embodiments, the lower supporter layer 142 may include the same material as the upper supporter layer 144. In some example embodiments, the lower supporter layer 142 and the upper supporter layer 144 may include different materials.

In various example embodiments, the dummy structure PSES may include a plurality of slits DS. The slits DS may be filled with an interlayer insulating layer 170. In the edge area EA, the slits DS may be arranged in a matrix along the first horizontal direction (the X direction) and the second horizontal direction (the Y direction). In addition, the slits DS may be arranged apart from each other on the dummy structure PSES in the first horizontal direction (the X direction). The slits DS may penetrate, in the vertical direction (the Z direction), the first mold layer 132, the lower supporter layer 142, the second mold layer 134, the upper supporter layer 144, and the upper electrode UE that form the dummy structure PSES. A portion of the upper surface of the insulating pattern 126P may be exposed through the slits DS. The length of each slit DS in the second horizontal direction (the Y direction) may be less than that of the dummy structure PSES in the second horizontal direction (the Y direction). That is, the slits DS may be formed inside the dummy structure PSES, and the dummy structure PSES may not be spaced by the slits DS. In various example embodiments, each slit DS may have a rectangular shape in a plan view. In various example embodiments, in a planar view, an area of the dummy structure PSES may be about 0.75 times to about 0.8 times the area of the edge area EA. Here, the area of the dummy structure PSES refers to an area of a portion of the edge area EA where the dummy structure PSES is located, and an area of a region where the slits DS are formed may not be included in the area of the dummy structure PSES. Therefore, by adjusting the size of each slit DS, the size of the area of the dummy structure PSES may be adjusted. When the area of the dummy structure PSES is in a range greater than the aforementioned range, there may be a residue of the interlayer insulating layer 170 in the edge area EA after the planarization process described below.

In the chip area CA and the edge area EA, the interlayer insulating layer 170 covering the capacitor structures CP and the dummy structures PSES may be arranged. The interlayer insulating layer 170 may cover the capacitor structures CP and the dummy structures PSES and fill the slits DS. The interlayer insulating layer 170 may include, for example, SiO₂.

The semiconductor device 100 according to various example embodiments may be in the edge area EA and include the dummy structure PSES including the slits DS. As the dummy structure PSES includes the slits DS, the area of the dummy structure PSES may be adjusted, and by adjusting the area, a problem concerning the residue of the interlayer insulating layer 170 remaining in the edge area EA during the planarization process described below may be reduced or prevented. Accordingly, the reliability of the semiconductor device 100 may be improved.

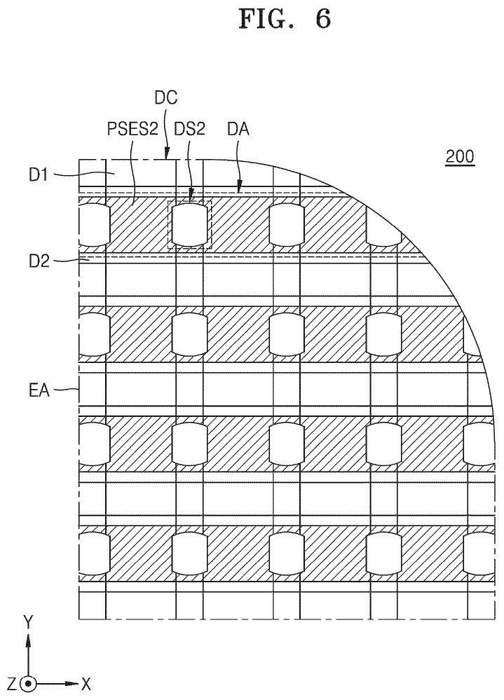

FIG. 6 illustrates a schematic layout of an edge area of a semiconductor device 200, according to various example embodiments. Because the respective components of the semiconductor device 200 of FIG. 6 are similar to those of the semiconductor device 100 described above with reference to FIGS. 1 to 5, the differences therebetween are mainly described.

Referring to FIG. 6, the semiconductor device 200 may have a structure that is substantially similar to the structure of the semiconductor device 100 of FIGS. 1 to 5 except that the semiconductor device 200 includes a plurality of slits DS2 that are different from the slits DS of the semiconductor device 100 on a plane.

The semiconductor device 200 may include a dummy structure PSES2 including the slits DS2. In the edge area EA, the slits DS2 may be arranged in a matrix form along the first horizontal direction (the X direction) and the second horizontal direction (the Y direction). In addition, the slits DS2 may be arranged apart from each other on the dummy structure PSES2 in the first horizontal direction (the X direction). The length of each slit DS2 in the second horizontal direction (the Y direction) may be less than that of the dummy structure PSES2 in the second horizontal direction (the Y direction). That is, the dummy structure PSES2 may not be separated by the slits DS2. In various example embodiments, in a planar view, each slit DS2 may have a rectangular shape in which opposite sides are convex. For example, each slit DS2 may have a rectangular shape in which sides facing each other in the second horizontal direction (the Y direction) are convex outwards. In various example embodiments, in a planar view, an area of the dummy structure PSES2 may be about 0.75 times to about 0.8 times the area of the edge area EA.

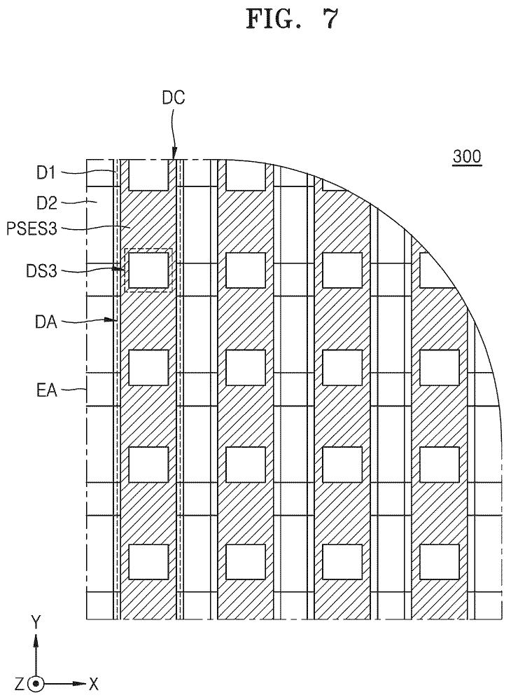

FIG. 7 illustrates a schematic layout of an edge area of a semiconductor device 300, according to various example embodiments. Because the respective components of the semiconductor device 300 of FIG. 7 are similar to those of the semiconductor device 100 described above with reference to FIGS. 1 to 5, the differences therebetween are mainly described.

Referring to FIG. 7, the semiconductor device 300 may have a structure that is substantially similar to that of the semiconductor device 100 of FIGS. 1 to 5 except that the semiconductor device 300 includes a dummy structure PSES3 extending in a direction different from the extension direction of the dummy structure PSES of the semiconductor device 100.

The semiconductor device 300 may include the dummy structure PSES3 extending in the second horizontal direction (the Y direction). In addition, the dummy structures PSES3 may be spaced apart from each other in the first horizontal direction (the X direction). The dummy structure PSES3 may include a plurality of slits DS3. In the edge area EA, the slits DS3 may be arranged in a matrix along the first horizontal direction (the X direction) and the second horizontal direction (the Y direction). In addition, the slits DS3 may be arranged apart from each other on the dummy structure PSES3 in the second horizontal direction (the Y direction). In various example embodiments, the length of each slit DS3 in the first horizontal direction (the X direction) may be less than that of the dummy structure PSES3 in the first horizontal direction (the X direction). That is, the dummy structure PSES3 may not be separated by the slits DS3.

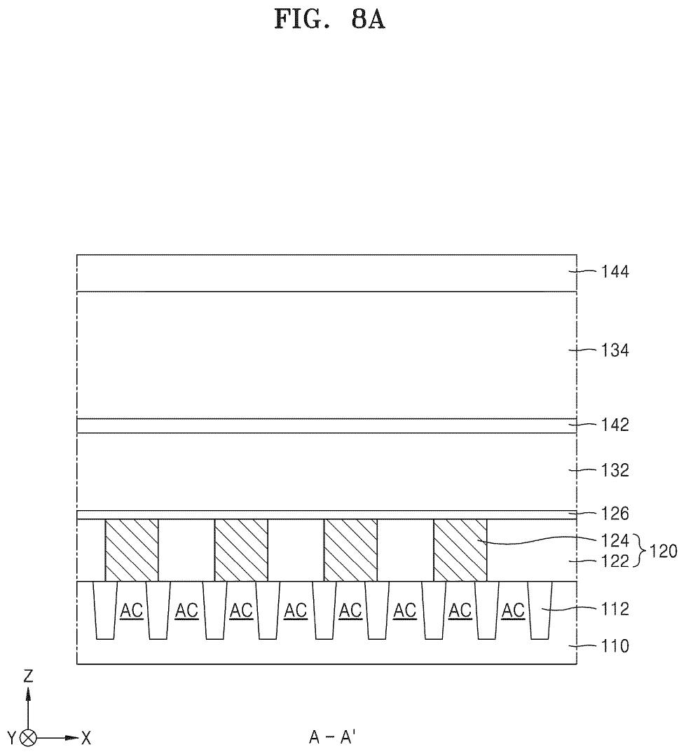

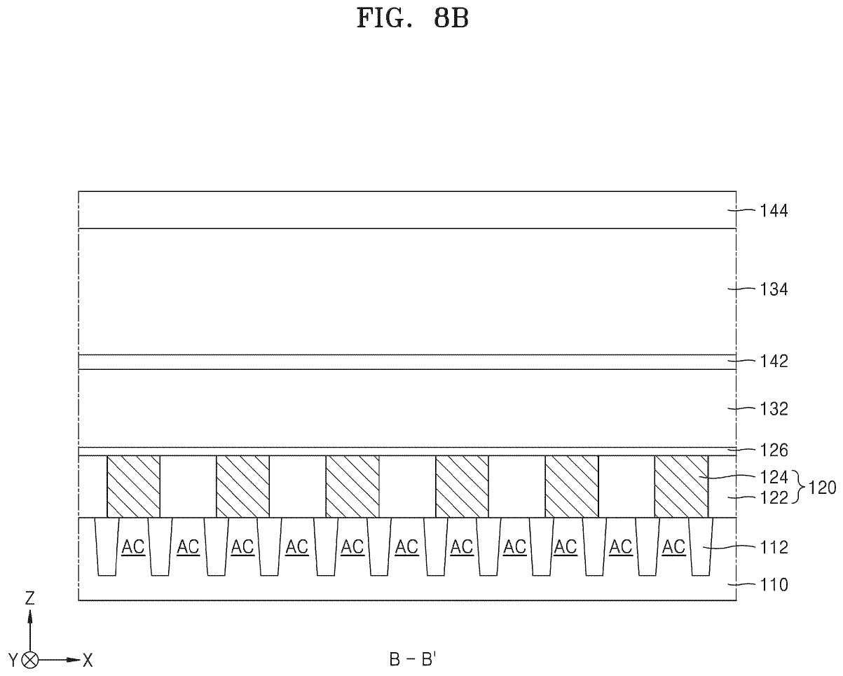

FIGS. 8A, 8B, 9, 10, 11A, 11B, 12A, 12B, 13A, and 13B respectively are cross-sectional views of a method of manufacturing the semiconductor device 100, according to various example embodiments. In detail, FIGS. 8A, 9, 10, 11A, 12A, and 13A respectively are cross-sectional views illustrating operations of the method of manufacturing the semiconductor device 100, taken along a line A-A′ of FIG. 2, and FIGS. 8B, 11B, 12B, and 13B respectively are cross-sectional views illustrating operations of the method of manufacturing the semiconductor device 100, taken along a line B-B′ of FIG. 3.

Referring to FIGS. 8A and 8B, the substrate 110, in which the active areas AC are defined by the device isolation layer 112, is provided first, and the lower structure 120, which includes the insulating structures 122 on the substrate 110 and the conductive areas 124 penetrating the insulating structures 122 and respectively connected to the active areas AC, may be formed on the provided substrate 110. Then, the insulating layer 126 covering the lower structure 120 may be formed. The insulating layer 126 may be used as an etch stop layer during the manufacturing processes of the semiconductor device 100. The insulating layer 126 may include an insulating material with an etch selectivity with respect to the insulating structures 122. In various example embodiments, the insulating layer 126 may include a SiN layer, a SiCN layer, a SiBN layer, or a combination thereof.

Next, in the chip area CA and the edge area EA, the first mold layer 132, the lower supporter layer 142, the second mold layer 134, and the upper supporter layer 144 may be sequentially stacked on the insulating layer 126. The first mold layer 132 and the second mold layer 134 may each include a material with a relatively high etch rate for an etchant containing ammonium fluoride (NH₄F), hydrofluoric acid (HF), and water. In various example embodiments, the first mold layer 132 and the second mold layer 134 may each include an oxide layer, a nitride layer, or a combination thereof. However, example embodiments are not limited thereto. For example, the first mold layer 132 may include a BPSG layer, and the second mold layer 134 may include a multilayered insulating layer in which a relatively thin silicon oxide layer and a relatively thin silicon nitride layer are alternately stacked one by one several times, or a silicon nitride layer. The lower supporter layer 142 and the upper supporter layer 144 may each include a SiN layer, a SiCN layer, a SiBN layer, or a combination thereof. However, example embodiments are not limited thereto.

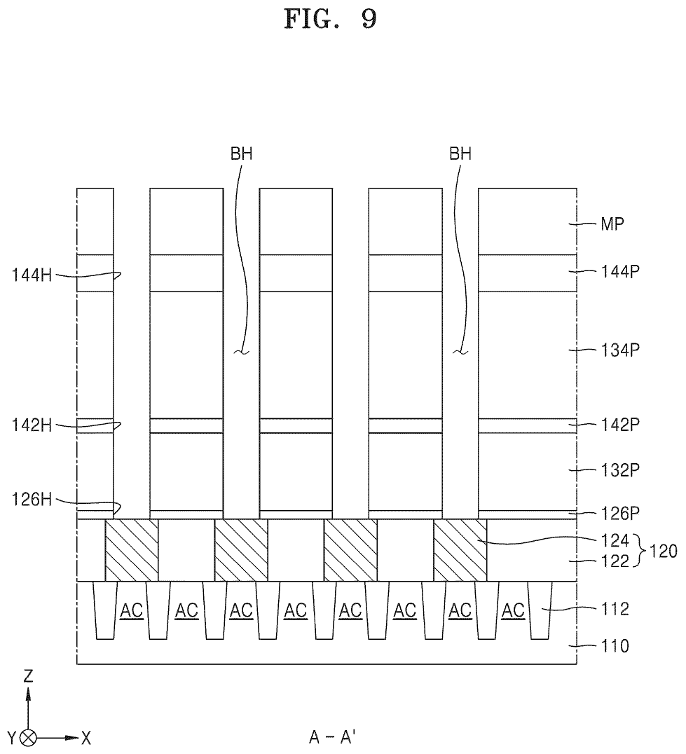

Referring to FIG. 9, after a mask pattern MP is formed on the upper supporter layer 144 in the result of FIGS. 8A and 8B, a plurality of holes BH may be formed by using the mask pattern MP as an etch mask and etching the first mold layer 132, the lower supporter layer 142, the second mold layer 134, and the upper supporter layer 144 by using the insulating layer 126 as an etch stop layer. After being etched through the etching process, the first mold layer 132, the lower supporter layer 142, the second mold layer 134, and the upper supporter layer 144 may become a first mold pattern 132P, a lower supporter 142P, a second mold pattern 134P, and an upper supporter 244P, respectively.

The mask pattern MP may include a nitride layer, an oxide layer, a polysilicon layer, a photoresist layer, or a combination thereof. However, example embodiments are not limited thereto.

The process of forming the holes BH may further include etching the first mold layer 132, the lower supporter layer 142, the second mold layer 134, and the upper supporter layer 144 and performing wet treatment thereon. While the wet treatment process is performed, a portion of the insulating layer 126 is etched together such that the insulating pattern 126P including the openings 126H exposing the conductive areas 124 may be obtained. An etchant including, for example, a diluted sulfuric acid peroxide (DSP) solution, may be used during the wet treatment process, but various example embodiments are not limited thereto.

The holes 142H forming portions of the holes BH may be formed in the lower supporter 142P, and the holes 144H forming portions of the holes BH may be formed in the upper supporter 144P.

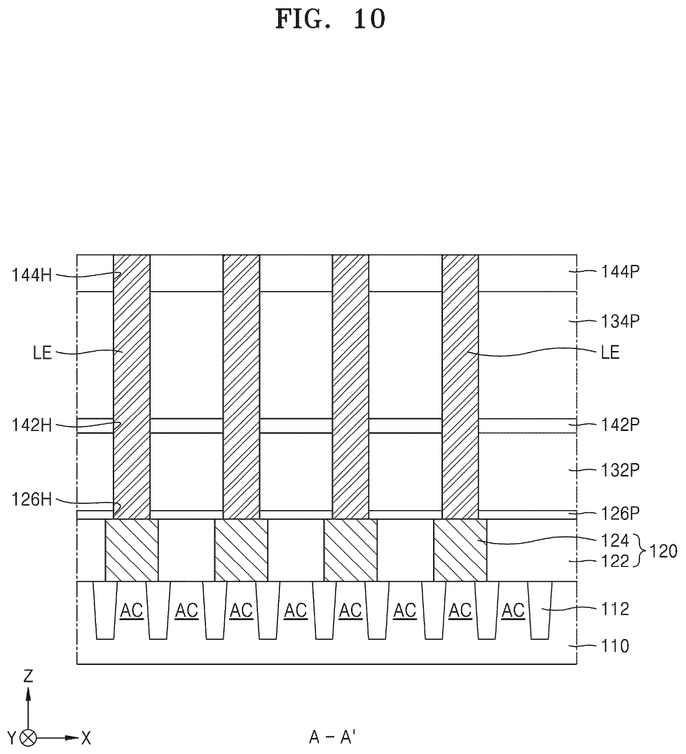

Referring to FIG. 10, in the result of FIG. 9, the lower electrode LE filling the holes BH may be formed after the removal of the mask pattern MP.

A conductive layer filling the holes BH and covering an upper surface of the upper supporter 144P may be formed to form the lower electrode LE. The process of forming the conductive layer may be, for example, chemical vapor deposition (CVD), plasma-enhanced CVD (PECVD), metal organic CVD (MOCVD), or atomic layer deposition (ALD). However, example embodiments are not limited thereto. After the conductive layer is formed, a portion of the conductive layer is removed through an etch-back process or a chemical mechanical polishing (CMP) process to expose the upper surface of the upper supporter 144P.

Referring to FIGS. 11A and 11B, in the result of FIG. 10, a first mask pattern (not shown) may be formed in the chip area CA, and a second mask pattern (not shown) may be formed in the edge area EA.

Next, in the chip area CA, a portion of the upper supporter 144P is removed using the first mask pattern to form a plurality of upper holes UH, and then the second mold pattern 134P may be removed through the upper holes UH. Then, after a portion of the lower supporter 142P is removed through the upper holes UH to form a plurality of lower holes LH, the first mold pattern 132P may be removed through the lower holes LH. Each upper hole UH may communicate with each lower hole LH, and the upper surface of the insulating pattern 126P may be exposed through the upper holes UH and the lower holes LH. In addition, the sidewalls of the lower electrodes LE may be exposed as the first mold pattern 132P and the second mold pattern 134P are removed.

In various example embodiments, the second mold pattern 134P and the first mold pattern 132P may be removed in a wet manner. An etchant including, for example, NH₄F, HF, and water, may be used during the wet removal process, but various example embodiments are not limited thereto.

In the edge area EA, a plurality of openings DSH penetrating the first mold layer 132, the lower supporter layer 142, the second mold layer 134, and the upper supporter layer 144, all of which are stacked on the insulating pattern 126P, may be formed using the second mask pattern.

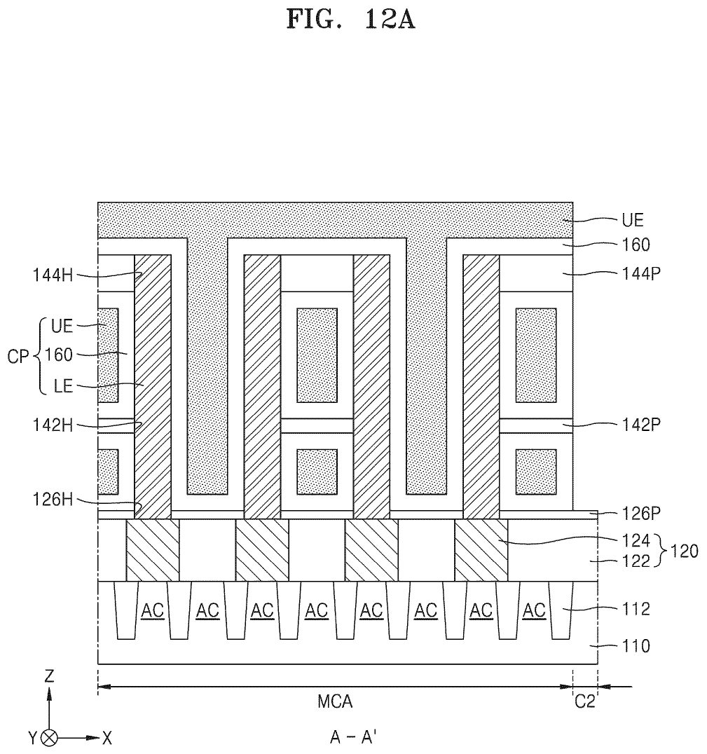

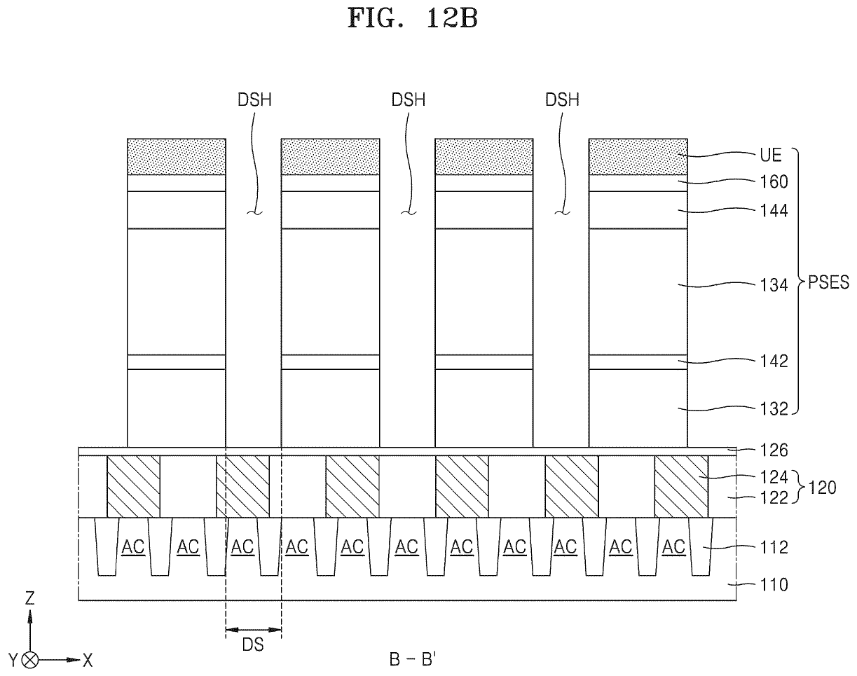

Referring to FIGS. 12A and 12B, in the result of FIGS. 11A and 11B, the dielectric layer 160 may be formed, wherein the dielectric layer 160 covers, in the chip area CA, the exposed sidewalls of the lower electrodes LE, some surfaces of the lower supporter 142P and the upper supporter 144P, and some surfaces of the insulating pattern 126P and covers the upper supporter layer 144 in the edge area EA. Next, the upper electrode UE covering the dielectric layer 160 may be formed. In various example embodiments, the upper electrode UE may be formed through CVD, MOCVD, PVD, or ALD. However, example embodiments are not limited thereto. In this case, the dielectric layer 160 and the upper electrode UE formed on the core area PS, the dummy core area DC, and the openings DSH may be removed using an etch mask after the formation of the etch mask (not shown). Through the processes described with reference to FIGS. 12A and 12B, the capacitor structures CP may be formed in the chip area CA and the dummy structures PSES may be formed in the edge area EA.

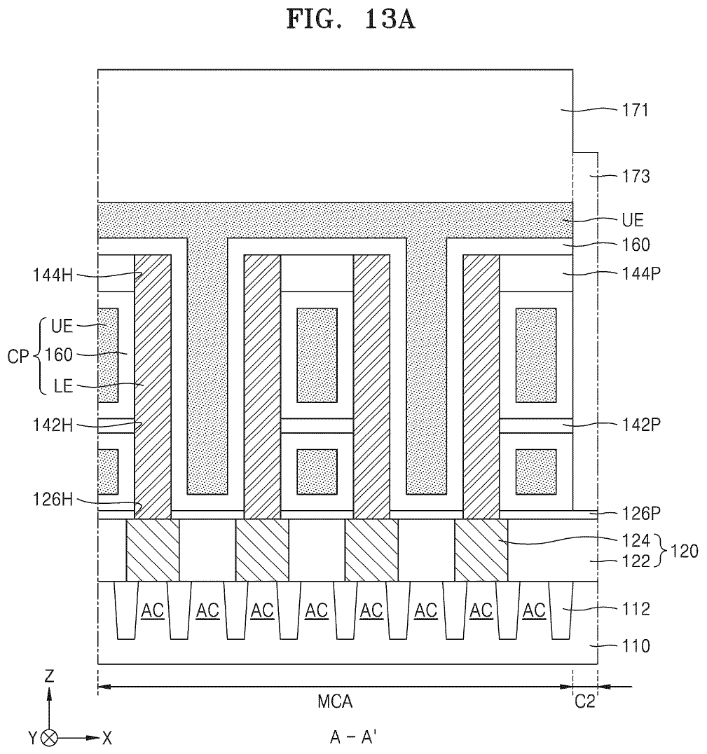

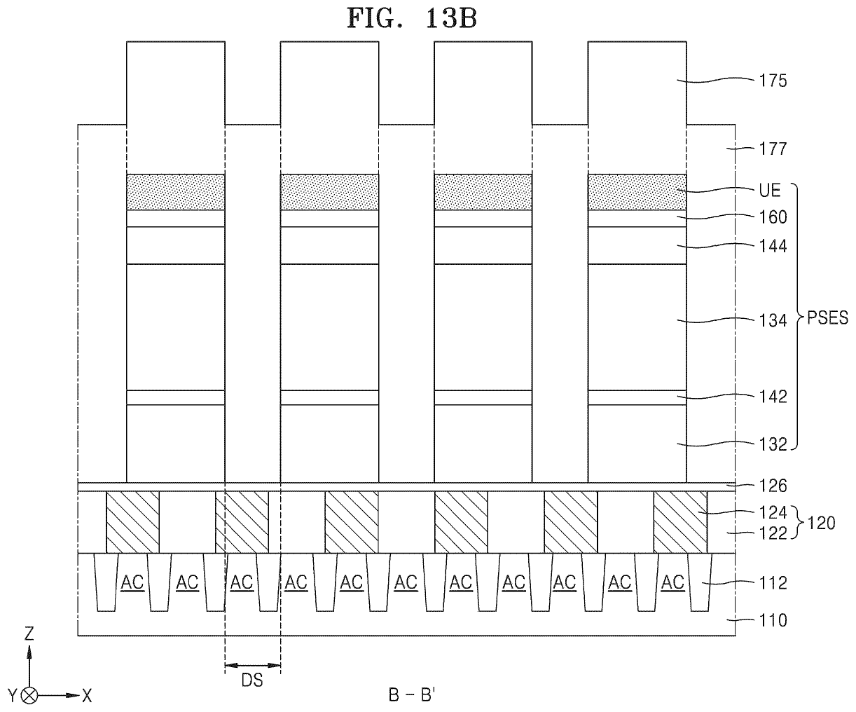

Referring to FIGS. 13A and 13B, in the result of FIGS. 12A and 12B, a first insulating material layer 171, a second insulating material layer 173, a third insulating material layer 175, and a fourth insulating material layer 177 may be formed in the chip area CA and the edge area EA. The first insulating material layer 171 may be formed in the memory cell area MCA of the chip area CA and the second insulating material layer 173 may be formed in the core area PS of the chip area CA. The third insulating material layer 175 may be formed in the dummy cell area DA of the edge area EA and the fourth insulating material layer 177 may be formed in the dummy core area DC of the edge area EA. The first insulating material layer 171 and the second insulating material layer 173 may be integrally formed, and the third insulating material layer 175 and the fourth insulating material layer 177 may be integrally formed. The first insulating material layer 171 may be at a higher vertical level than the second insulating material layer 173, and the third insulating material layer 175 may be at a higher vertical level than the fourth insulating material layer 177. In addition, the first insulating material layer 171 may be at the same vertical level as the third insulating material layer 175, and the second insulating material layer 173 may be at the same vertical level as the fourth insulating material layer 177.

In the result of FIGS. 13A and 13B, a planarization process is performed to substantially planarize the first insulating material layer 171, the second insulating material layer 173, the third insulating material layer 175, and the fourth insulating material layer 177. The planarization process may be, for example, a CMP process. As the first insulating material layer 171, the second insulating material layer 173, the third insulating material layer 175, and the fourth insulating material layer 177 are substantially planarized, the interlayer insulating layer 170 (see FIG. 4) covering the capacitor structures CP and the dummy structures PSES in the chip area CA and the edge area EA may be formed.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

While the inventive concepts have been particularly shown and described with reference to various example embodiments thereof, it will be understood that various changes in form and details may be made therein without departing from the spirit and scope of the following claims.

What is claimed is:

1. A semiconductor device comprising:
a substrate including a chip area and an edge area surrounding the chip area;
a plurality of capacitor structures in the chip area of the substrate;
a plurality of dummy structures in the edge area of the substrate; and
an interlayer insulating layer covering the plurality of capacitor structures and the plurality of dummy structures,
wherein each of the plurality of dummy structures comprises a plurality of slits, and
the plurality of slits are filled with the interlayer insulating layer.

2. The semiconductor device of claim 1, wherein the plurality of dummy structures extend in a first horizontal direction.

3. The semiconductor device of claim 2, wherein lengths of the plurality of slits in a second horizontal direction are less than lengths of the plurality of dummy structures in the second horizontal direction.

4. The semiconductor device of claim 1, wherein the plurality of slits are arranged in the edge area in a matrix along a first horizontal direction and a second horizontal direction.

5. The semiconductor device of claim 1, wherein each of the plurality of slits has a rectangular shape in a plan view.

6. The semiconductor device of claim 1, wherein, in a plan view, each of the plurality of slits has a rectangular shape with two opposite sides being convex.

7. The semiconductor device of claim 1, wherein, in a planar view, an area of the plurality of dummy structures is 0.75 times to 0.80 times an area of the edge area.

8. The semiconductor device of claim 1, wherein the plurality of dummy structures extend in a horizontal direction.

9. The semiconductor device of claim 1, wherein a length of each of the plurality of slits in a first horizontal direction are less than a length of each of the plurality of dummy structures in the first horizontal direction, and the plurality of dummy structures extend in a second horizontal direction.

10. A semiconductor device comprising:
a substrate including a chip area and an edge area surrounding the chip area;
a lower structure arranged on the substrate and comprising a plurality of conductive areas;
a plurality of capacitor structures arranged on the lower structure in the chip area;
a plurality of dummy structures arranged on the lower structure in the edge area; and
an interlayer insulating layer covering the plurality of capacitor structures and the plurality of dummy structures,
wherein each of the plurality of dummy structures includes a plurality of slits, and
the plurality of slits are filled with the interlayer insulating layer.

11. The semiconductor device of claim 10, wherein the plurality of dummy structures extend in a first horizontal direction, and the plurality of dummy structures are spaced apart from each other in a second horizontal direction.

12. The semiconductor device of claim 11, wherein the plurality of slits are spaced apart from each other in the first horizontal direction.

13. The semiconductor device of claim 11, wherein a length of each of the plurality of slits in the second horizontal direction is less than a length of each of the plurality of dummy structures in the second horizontal direction.

14. The semiconductor device of claim 10, wherein the plurality of slits are arranged in the edge area in a matrix along a first horizontal direction and a second horizontal direction.

15. The semiconductor device of claim 10, wherein, in a planar view, an area of each of the plurality of dummy structures is 0.75 times to 0.80 times an area of the edge area.

16. The semiconductor device of claim 10, wherein the plurality of dummy structures are spaced apart from each other in a first horizontal direction and extend in a second horizontal direction.

17. The semiconductor device of claim 16, wherein the plurality of slits are spaced apart from each other in the second horizontal direction.

18. The semiconductor device of claim 16, wherein a length of each of the plurality of slits in the first horizontal direction is less than a length of each of the plurality of dummy structures in the first horizontal direction.

19. A semiconductor device comprising:
a substrate including a chip area and an edge area surrounding the chip area;
the chip area includes a memory cell area and a core area surrounding the memory cell area;
the edge area comprises a dummy cell area and a dummy core area surrounding the dummy cell area;
a lower structure is arranged on the substrate and includes a plurality of conductive areas;
a plurality of capacitor structures arranged on the lower structure in the memory cell area;
a plurality of dummy structures arranged on the lower structure in the dummy cell area; and
an interlayer insulating layer covering the plurality of capacitor structures and the plurality of dummy structures,
wherein each of the plurality of dummy structures comprises a plurality of slits that are arranged apart from each other in an extension direction of the plurality of dummy structures, and
the plurality of slits are filled with the interlayer insulating layer.

20. The semiconductor device of claim 19, wherein the plurality of slits are arranged in the edge area in a matrix along a first horizontal direction and a second horizontal direction.
